(19) United States
(12) Patent Application Publication
(10) Pub. No.: US 2014/0159025 A1
(43) Pub. Date: Jun. 12, 2014

(54) MESOPOROUS SILICA PARTICLES, METHOD FOR PRODUCING MESOPOROUS SILICA PARTICLES, MESOPOROUS SILICA PARTICLE-CONTAINING COMPOSITION, MESOPOROUS SILICA PARTICLE-CONTAINING MOLDED ARTICLE, AND ORGANIC ELECTROLUMINESCENCE DEVICE

(71) Applicant: PANASONIC CORPORATION, Osaka (JP)

(72) Inventors: Ayumu Fukuoka, Osaka (JP); Masahito Yamana, Hyogo (JP)

(73) Assignee: PANASONIC CORPORATION, Osaka (JP)

(21) Appl. No.: 14/130,279

(22) PCT Filed: Jul. 8, 2013
(86) PCT No.: PCT/JP2013/004221

§ 371 Date: Dec. 30, 2013

(30) Foreign Application Priority Data
Aug. 10, 2012 (JP) 2012-177914

(51) Int. Cl. H01L 51/52

(52) U.S. Cl. CPC H01L 51/5203
USPC 257/40; 252/582

(57) ABSTRACT

The mesoporous silica particles of the present invention each include an inner portion having first mesopores and an outer peripheral portion covering the inner portion. The outer peripheral portion includes an organosilica coating portion made of organosilica. The organosilica includes a bridged-type organosilica in which two silicon atoms in a silica framework are bridged by an organic group.

### TECHNICAL FIELD

The present invention relates to mesoporous silica particles, a method for producing mesoporous silica particles, a composition obtained using the mesoporous silica particles, a molded article obtained using the composition, and an organic electroluminescence device obtained using the mesoporous silica particles.

### BACKGROUND ART

Silica particles having a hollow structure as described in Patent Literature 1 are conventionally known as fine particles used to achieve a low reflectance (Low-n) and/or a low dielectric constant (Low-k). Recently, there has been a demand for a higher porosity to achieve higher performance. However, it is difficult to reduce the thickness of the outer shell of hollow silica particles, and if the particle size is reduced to 100 nm or less, the porosity is more likely to decrease for structural reasons.

Under these circumstances, mesoporous silica particles are expected as next generation high porosity particles that are applicable to low reflectance (Low-n) materials, low dielectric constant (Low-k) materials, and further low thermal conductivity materials, because the mesoporous silica particles are characterized in that their porosity hardly decreases for structural reasons even if their particle size is reduced. A molded article having the above-mentioned properties can be obtained by dispersing mesoporous silica particles in a matrix material such as a resin (see Patent Literatures 2 to 6). Core-shell type mesoporous silica particles having a mesoporous shell structure also are proposed (see Patent Literature 7).

### CITATION LIST

### Patent Literature

Patent Literature 1: JP 2001-233611 A

Patent Literature 2: JP 2009-040965 A

Patent Literature 3: JP 2009-040966 A

Patent Literature 4: JP 2009-040967 A

Patent Literature 5: JP 2004-083307 A

Patent Literature 6: JP 2007-161518 A

Patent Literature 7: JP 2009-263171 A

### Non-Patent Literature

Non-Patent Literature 1: Microporous and Mesoporous Materials 120 (2009) 447-453

### SUMMARY OF INVENTION

### Technical Problem

In order to produce a molded article having excellent properties of mesoporous silica particles, the molded article must contain high porosity mesoporous silica particles. However, conventional mesoporous silica particles have the following disadvantages. A molded article or the like having a low content of such mesoporous silica particles cannot fully exhibit the above-mentioned properties because their porosity is small, whereas a molded article having a high content of such mesoporous silica particles has reduced their mechanical strength. There have been attempts to further increase the porosity of mesoporous silica particles. For example, Non-Patent Literature 1 describes a technique for increasing the size of mesopores of particles by adding stylene or the like so as to increase the void volume of the particles. However, since the shape and arrangement of the mesopores obtained by this method lack regularity, the strength of the particles is reduced, which may result in a decrease in the strength of the molded article. In addition, the increase in the size of the mesopores allows a matrix material to easily penetrate into the mesopores, which may make it difficult for the molded article to exhibit the properties such as a low reflectance (Low-n), a low dielectric constant (Low-k), and/or a low thermal conductivity.

Furthermore, in order to improve the properties of a molded article compounded with mesoporous silica particles, the mesoporous silica particles must be highly dispersed in the molded article. However, for conventional mesoporous silica particles, further improvement in the dispersibility is required.

The present invention has been made in view of the above problems, and it is an object of the present invention to provide mesoporous silica particles capable of imparting both high strength and excellent properties such as a low reflectance (Low-n), a low dielectric constant (Low-k), and/or a low thermal conductivity to a molded article.

### Solution to Problem

The present invention provides mesoporous silica particles each including: an inner portion having first mesopores; and an outer peripheral portion covering the inner portion, wherein the outer peripheral portion includes an organosilica coating portion made of organosilica, and the organosilica includes a bridged-type organosilica in which two silicon atoms in a silica framework are bridged by an organic group.

### Advantageous Effects of Invention

According to the present invention, it is possible to provide mesoporous silica particles having increased dispersibility in a matrix material, capable of inhibiting penetration of the matrix material into mesopores, and capable of imparting both high mechanical strength and excellent properties such as a low reflectance (Low-n) and/or a low dielectric constant (Low-k), and a low thermal conductivity to a molded article.

### BRIEF DESCRIPTION OF DRAWINGS

FIG. 1 is a cross-sectional view showing an example of an organic electroluminescence device according to an embodiment of the present invention.

FIG. 2A is a transmission electron microscope (TEM) image of mesoporous silica particles of Example 1.

FIG. 2B is a TEM image of the mesoporous silica particles of Example 1.

FIG. 3A is a TEM image of mesoporous silica particles of Example 2.

FIG. 3B is a TEM image of the mesoporous silica particles of Example 2.

FIG. 4A is a TEM image of mesoporous silica particles of Example 3.

FIG. 4B is a TEM image of the mesoporous silica particles of Example 3.

FIG. 5A is a TEM image of mesoporous silica particles of Comparative Example 1.

FIG. 5B is a TEM image of the mesoporous silica particles of Comparative Example 1.

### DESCRIPTION OF EMBODIMENTS

The present inventors have found that conventional mesoporous silica particles are disadvantageous when they are dispersed in a material for forming a matrix (a matrix material) to form a molded article. Since the conventional mesoporous silica particles have a hydrophilic surface, they are hardly dispersed in a hydrophobic matrix material, although they are relatively easily dispersed in a hydrophilic matrix material. As a result of intensive studies, the present inventors have provided mesoporous silica particles having high dispersibility in matrix materials and thus capable of further improving the properties of the resulting molded article. In addition, the present inventors have provided a method for producing such mesoporous silica particles. Furthermore, the present inventors have provided a composition obtained using the mesoporous silica particles, a molded article obtained using the composition, and an organic electroluminescence device (hereinafter referred to as an “organic EL device”) obtained using the mesoporous silica particles.

A first aspect of the present invention provides mesoporous silica particles each including: an inner portion having first mesopores; and an outer peripheral portion covering the inner portion, wherein the outer peripheral portion includes an organosilica coating portion made of organosilica, and the organosilica includes a bridged-type organosilica in which two silicon atoms in a silica framework are bridged by an organic group.

The mesoporous silica particles according to the first aspect each has the outer peripheral portion including the organosilica coating portion. Therefore, the particle surface can be made hydrophobic by selecting appropriate organic groups as those contained in the organosilica, and hence even if the matrix material constituting a molded article is hydrophobic, excellent dispersibility of the mesoporous silica particles in the matrix material can be obtained. In addition, since the organosilica coating portion contains a bridged-type organosilica, the organic groups are incorporated into the framework and uniformly arranged in the organosilica coating portion. Accordingly, the mesoporous silica particles can uniformly exhibit the properties such as uniform dispersibility in the matrix material and uniform reactivity therewith. Furthermore, since the inner portion having mesopores is covered by the outer peripheral portion, the matrix material hardly penetrates into the mesopores of the inner portion. Therefore, even if the content of the mesoporous silica particles is not high, the molded article can fully exhibit the properties such as a low reflectance (Low-n), a low dielectric constant (Low-k), and/or a low thermal conductivity. Thereby, the mesoporous silica particles according to the first aspect can impart both high mechanical strength and the properties such as a low reflectance (Low-n), a low dielectric constant (Low-k), and/or a low thermal conductivity to the resulting molded article.

A second aspect of the present invention provides mesoporous silica particles as set forth in the first aspect, wherein the organosilica coating portion has second mesopores smaller in size than the first mesopores.

According to the mesoporous silica particles of the second aspect, it is possible to increase the porosity of the particles while keeping the matrix material constituting the molded article from penetrating into the mesopores of the inner portions.

A third aspect of the present invention provides a method for producing mesoporous silica particles, including: a surfactant-composited silica particle preparing step of preparing surfactant-composited silica particles by mixing a first surfactant, water, an alkali, a hydrophobic part-containing additive, and a silica source, the hydrophobic part-containing additive including a hydrophobic part serving to increase a volume of a micelle formed by the first surfactant; and an organosilica coating step of coating at least part of a surface of each of the surfactant-composited silica particles with organosilica by adding an organosilica source to the surfactant-composited silica particles.

According to the production method of the third aspect of the present invention, it is possible to produce mesoporous silica particles having high dispersibility in the matrix material, capable of inhibiting penetration of the matrix material into the mesopores, and capable of imparting both high strength and excellent properties such as a low reflectance (Low-n), a low dielectric constant (Low-k), and/or a low thermal conductivity to the resulting molded article.

A fourth aspect of the present invention provides a method for producing mesoporous silica particles as set forth in the third aspect, wherein in the organosilica coating step, the organosilica source and a second surfactant are added to the surfactant-composited silica particles so as to coat the at least part of the surface of each of the surfactant-composited silica particles with organosilica composited with the second surfactant.

According to the production method of the fourth aspect, it is possible to produce mesoporous silica particles including an organosilica coating portion having second mesopores smaller in size than the first mesopores.

A fifth aspect of the present invention provides a mesoporous silica particle-containing composition, including: the mesoporous silica particles according the first aspect or the second aspect; and a matrix material.

According to the composition of the fifth aspect, it is possible to easily produce a molded article having both high mechanical strength and excellent properties such as a low reflectance (Low-n), a low dielectric constant (Low-k), and/or a low thermal conductivity.

A sixth aspect of the present invention provides a mesoporous silica particle-containing molded article, obtained by molding the mesoporous silica particle-containing composition according to the fifth aspect into a predetermined shape.

The molded article according to the sixth aspect can achieve both high mechanical strength and excellent properties such as a low reflectance (Low-n), a low dielectric constant (Low-k), and/or a low thermal conductivity.

A seventh aspect of the present invention provides an organic electroluminescence device including: a first electrode; a second electrode; and an organic layer disposed between the first electrode and the second electrode and including a light-emitting layer, wherein the organic layer includes the mesoporous silica particles according to the first aspect or the second aspect.

In the organic EL device according to the seventh aspect, the organic layer including a light-emitting layer contains the mesoporous silica particles according to the first aspect or the second aspect. As described above, the mesoporous silica particles according to the first aspect or the second aspect can impart both high mechanical strength and excellent properties such as a low reflectance (Low-n), a low dielectric constant (Low-k), and/or a low thermal conductivity to the resulting molded article. Therefore, in the organic EL device of the seventh aspect, the refractive index of the organic layer including the light-emitting layer can be reduced, and hence high light emitting efficiency can be obtained.

Hereinafter, embodiments for carrying out the present invention are described.

[Mesoporous Silica Particles]

Mesoporous silica particles each include an inner portion having first mesopores and an outer peripheral portion covering the inner portion. In the case where the mesoporous silica particles have a core-shell structure, the inner portion and the outer peripheral portion serve as a core portion and a shell portion covering the core portion, respectively. The outer peripheral portion includes a portion formed of an organosilica coating. Hereinafter, in this description, the inner portion having the first mesopores is also referred to as a silica core. The portion formed of the organosilica coating is also referred to as an organosilica coating portion (or an organosilica shell). The organosilica forming the organosilica coating portion includes an organosilica having a structure in which two silicon atoms are bridged by an organic group in at least part of a silica framework (a bridged-type organosilica). As described above, the outer peripheral portion only has to include the organosilica coating portion, and the outer peripheral portion may further include a coating portion made of a material other than organosilica. In the present embodiment, however, the structure in which the outer peripheral portion consists of the organosilica coating portion is described as an example.

Preferably, the average particle diameter of the mesoporous silica particles is 100 nm or less. The mesoporous silica particles having this average particle diameter can be easily incorporated into a device structure that requires a low refractive index (Low-n), a low dielectric constant (Low-k), and/or a low thermal conductivity, and therefore they can be densely filled in the device. If the average particle diameter of the mesoporous silica particles is greater than this range, it may be difficult to densely fill them. The lower limit of the average particle diameter of the mesoporous silica particles is essentially 10 nm. The average particle diameter is preferably 20 to 100 nm. Herein, the particle diameter of the mesoporous silica particles is a diameter including the organosilica coating portion, that is, the outer peripheral portion, and is obtained by adding the thickness of the organosilica coating portion to the particle diameter of the silica core. The average particle diameter of the silica core can be, for example, 20 to 80 nm. The average particle diameter of the mesoporous silica particles is a value obtained by measuring the particle diameters of at least 30 mesoporous silica particles by direct observation with an electron microscope and calculating the arithmetic mean value of the measurement values thus obtained. It is also possible to determine the average particle diameter of the silica core using particles obtained by omitting an “organosilica coating step” and performing a “removing step” after a “surfactant-composited silica particle preparing step” in the production of the mesoporous silica particles described later. Specifically, the particle diameters of at least 30 particles are measured by direct observation with an electron microscope, and the arithmetic mean value of the measurement values thus obtained is calculated as the average particle diameter.

Preferably, the pore diameter of the first mesopores is 3.0 nm or more. Preferably, a plurality of first mesopores are formed at equal spacings in the inner portion of the mesoporous silica particle. When a composition containing such mesoporous silica particles is molded, this arrangement of equally spaced first mesopores makes it possible to achieve a sufficiently high porosity while maintaining the mechanical strength even, although the mechanical strength would decrease if the mesopores are unevenly distributed. If the diameter of the first mesopores is less than 3.0 nm, sufficient porosity may not be obtained. The diameter of the first mesopores is preferably 10 nm or less. If the diameter of the mesopores is greater than 10 nm, the porosity is too large, which may make the particles more brittle and decrease the mechanical strength of the molded article. The “equal spacing” does not mean a completely equal spacing, and it may be a spacing that is found to be a substantially equal spacing when it is observed with a TEM or the like. The pore diameter of the first mesopores is a value calculated from a pore size distribution obtained by the BJH (Barrett-Joyner-Halenda) analysis. This also applies to the pore diameter of the second mesopores.

The outer peripheral portion, that is, the organosilica coating portion (organosilica shell) covering the silica core in the present embodiment, may entirely cover the silica core or may partially cover the silica core. Thereby, some of the first mesopores exposed on the surface of the silica core can be covered, or the open area of the first mesopores can be reduced.

The thickness of the organosilica coating portion is preferably 30 nm or less. If the thickness is more than 30 nm, the porosity of the entire particle may be too small. If the mesoporous silica particles are used as a low refractive index material, the thickness of the organosilica coating portion is more preferably 10 nm or less because the refractive index can be reduced sufficiently. The thickness of the organosilica coating portion is preferably 1 nm or more. If the thickness is less than 1 nm, the coating amount may be too small to sufficiently cover the first mesopores or reduce the opening area thereof.

Preferably, the organosilica coating portion includes second mesopores smaller in size than the first mesopores. The presence of the second mesopores of the organosilica coating portion having a smaller pore diameter than the first mesopores makes it possible to increase the porosity of the particles while inhibiting the matrix material such as a resin from penetrating into the first mesopores.

Preferably, the pore diameter of the second mesopores is 2 nm or more. Preferably, a plurality of second mesopores are formed at equal spacings in the organosilica coating portion. When a composition containing such mesoporous silica particles is molded, this arrangement of equally spaced second mesopores makes it possible to achieve a sufficiently high porosity while maintaining the strength even, although the strength would decrease if the mesopores are unevenly distributed. If the diameter of the second mesopores is less than 2 nm, sufficient porosity may not be obtained. Preferably, the pore diameter of the second mesopores is 90% or less of the pore diameter of the first mesopores. If the pore diameter of the second mesopores is larger than 90% of the pore diameter of the first mesopores, the difference between the pore diameter of the first mesopores and that of the second mesopores is very small, and the effect of the coating may not develop. The “equal spacing” does not mean a completely equal spacing, and it may be a spacing that is found to be a substantially equal spacing when it is observed with a TEM or the like.

The mesoporous silica particles each include the organosilica coating portion. This means that organic groups contained in organosilica are present on the surface of the mesoporous silica particles. The presence of such organic groups can improve the properties of the mesoporous silica particles, such as the dispersibility in the matrix material and the reactivity therewith. Preferably, the mesoporous silica particles further include other organic groups on the surface thereof, in addition to the organic groups contained in the organosilica forming the organosilica coating portion. The introduction of the additional organic groups can further improve the properties such as dispersibility and reactivity.

Preferably, the organic groups are uniformly arranged on the surface of the mesoporous silica particles. Such an uniform arrangement of the organic groups allows the particles to exhibit improved properties such as dispersibility and reactivity uniformly. The organosilica forming the organosilica coating portion includes a bridged-type organosilica having a structure in which two silicon atoms are bridged by an organic group in part of a silica framework. The organosilica forming the organosilica coating portion may consist of a bridged-type organosilica. Such a bridged-type organosilica is preferred because the organic groups are arranged more uniformly.

The organic groups on the surface of the mesoporous silica particles are preferably hydrophobic functional groups. Such mesoporous silica particles have improved dispersibility in a solvent in a liquid dispersion, and improved dispersibility in a resin in a resin composition. Therefore, a molded article in which the particles are uniformly dispersed can be obtained. When a molded article is produced using densely filled mesoporous silica particles, water may penetrate into the mesopores and other empty pores of the particles during or after the molding, resulting in a deterioration in the quality of the molded article. However, the hydrophobic functional groups prevent such water adsorption, a high-quality molded article can be obtained.

The hydrophobic functional group is not particularly limited. In the case where this hydrophobic functional group is a functional group constituting the organosilica forming the organosilica coating portion and is a divalent functional group bridging two silicon atoms, examples of this functional group include hydrophobic organic groups like alkylene groups such as methylene, ethylene, and butylene groups, and divalent aromatic groups such as phenylene and biphenylene groups. In the case where this hydrophobic functional group is a functional group that is additionally introduced onto the surface of the mesoporous silica particles, examples of this functional group include hydrophobic organic groups like alkyl groups such as methyl, ethyl, and butyl groups, and aromatic groups such as phenyl and biphenyl groups, and fluorine-substituted products of such hydrophobic organic groups. Preferably, these hydrophobic functional groups are provided in the organosilica coating portion. It is thus possible to increase the hydrophobicity effectively and increase the dispersibility accordingly.

Preferably, the mesoporous silica particles include reactive functional groups on the surface thereof. The reactive functional group is a functional group that reacts mainly with a resin forming the matrix. Therefore, the resin forming the matrix and the functional groups of the particles react with each other to form chemical bonds. Thus, the strength of the molded article can be increased. Preferably, these reactive functional groups are provided in the organosilica coating portion. It is thus possible to increase the reactivity effectively and increase the mechanical strength of the molded article accordingly.

The reactive functional group is not particularly limited, but is preferably an amino group, an epoxy group, a vinyl group, an isocyanate group, a mercapto group, a sulfide group, an ureido group, a methacryloxy group, an acryloxy group, a styryl group, or the like. Since these functional groups form chemical bonds with the resin, the adhesion between the mesoporous silica particles and the resin forming the matrix can be increased.

[Production of Mesoporous Silica Particles]

The method for producing the mesoporous silica particles of the present invention is not particularly limited, but it is preferable to use the following method. First, a “surfactant-composited silica particle preparing step” of preparing surfactant-composited silica particles having mesopores in which surfactant micelles containing a hydrophobic part-containing additive are present as a template is performed. Next, an “organosilica coating step” of adding an organosilica source to these surfactant-composited silica particles to coat at least part of the surface of each of the silica particles (silica cores) with organosilica is performed. And finally, a “removing step” of removing the surfactant and the hydrophobic part-containing additive contained in the surfactant-composited silica particles is performed.

(Surfactant-Composited Silica Particle Preparing Step)

In the surfactant-composited silica particle preparing step, first, a liquid mixture containing a surfactant (a first surfactant), water, an alkali, a hydrophobic part-containing additive including a hydrophobic part serving to increase the volume of micelles formed by the surfactant, and a silica source is prepared.

As the silica source, any suitable silica source (silicon compound) can be used as long as the silica source forms the inner portion having first mesopores in the mesoporous silica particles. Examples of such a silica source include silicon alkoxides, and specific examples of the silicon alkoxides include tetraalkoxysilanes such as tetramethoxysilane, tetraethoxysilane, and tetrapropoxysilane. It is particularly preferable to use tetraethoxysilane (Si(OC₂H₅)₄) because good mesoporous silica particles can be easily prepared.

Preferably, the silica source contains an alkoxysilane having an organic group. The use of such an alkoxysilane makes it possible to react the surfactant micelles containing a hydrophobic part-containing additive with the silica source more stably and thus to easily produce mesoporous silica particles whose inner portions have mesopores that are arranged at equal spacings.

The alkoxysilane having an organic group is not particularly limited as long as the alkoxysilane is capable of yielding surfactant-composited silica particles when used as a silica source. Examples thereof include alkoxysilanes containing organic groups such as alkyl, aryl, amino, epoxy, vinyl, mercapto, sulfide, ureido, methacryloxy, acryloxy, and styryl groups. An amino group is particularly preferred, and for example, a silane coupling agent such as aminopropyltriethoxysilane can be preferably used.

As the surfactant, any surfactant such as a cationic surfactant, an anionic surfactant, a non-ionic surfactant, or a triblock copolymer may be used, but a cationic surfactant is preferably used. The cationic surfactant is not particularly limited, but quaternary ammonium salt cationic surfactants such as octadecyltrimethylammonium bromide, hexadecyltrimethylammonium bromide, tetradecyltrimethylammonium bromide, dodecyltrimethylammonium bromide, decyltrimethylammonium bromide, octyl trimethylammoniumbromide, and hexyltrimethylammonium bromide are particularly preferred because they allow good mesoporous silica particles to be easily prepared.

The mixing ratio of the silica source and the surfactant is not particularly limited, but the weight ratio thereof is preferably 1:10 to 10:1. If the amount of the surfactant is outside this range of weight ratios relative to the silica source, the regularity of the structure of the resulting product is more likely to decrease, which may make it difficult to obtain mesoporous silica particles with a regular array of mesopores. In particular, when the weight ratio is 100:75 to 100:100, mesoporous silica particles with a regular array of mesopores can be easily obtained.

The hydrophobic part-containing additive is an additive having a hydrophobic part that has the effect of increasing the volume of the micelles formed by the surfactant as described above. If the hydrophobic part-containing additive is added, this additive is incorporated into the hydrophobic part of the surfactant micelles, and thus increases the volume of the micelles in the course of the alkoxysilane hydrolysis reaction. As a result, mesoporous silica particles with large first mesopores can be obtained. The hydrophobic part-containing additive is not particularly limited. Examples of the hydrophobic part-containing additive whose molecule is entirely hydrophobic include alkylbenzene, long-chain alkane, benzene, naphthalene, anthracene, and cyclohexane. Examples of the hydrophobic part-containing additive whose molecule is partially hydrophobic include block copolymer. Alkylbenzenes such as methylbenzene, ethylbenzene, and isopropylbenzene are particularly preferred because they are easily incorporated into the micelles and more likely to enlarge the first mesopores.

The technique of adding a hydrophobic additive to enlarge mesopores when preparing a mesoporous material is disclosed in the prior art documents “J. Am. Chem. Soc. 1992, 114, 10834-10843” and “Chem. Mater. 2008, 20, 4777-4782”. However, in the production method of the present invention, the use of the technique as described above makes it possible to enlarge the mesopores of mesoporous silica particles and thus increase the porosity thereof while maintaining the particles in the form of highly dispersible fine particles applicable to microdevices.

Preferably, the amount of the hydrophobic part-containing additive in the liquid mixture is at least three times the amount of the surfactant in terms of amount of substance (molar ratio). Thereby, sufficiently large mesopores can be obtained and particles with a higher porosity can be easily produced. If the amount of the hydrophobic part-containing additive is less than three times that of the surfactant, sufficiently large mesopores may not be obtained. Even if an excessive amount of the hydrophobic part-containing additive is contained, the excess hydrophobic part-containing additive is not incorporated into the micelles and has less influence on the reaction of the particles. Therefore, the upper limit of the amount of the hydrophobic part-containing additive is not particularly limited, but it is preferably 100 times or less in view of the efficiency of the hydrolysis reaction. Further preferably, the amount of the hydrophobic part-containing additive is at least three times but not more than 50 times.

Preferably, the liquid mixture contains alcohol. The use of the liquid mixture containing alcohol makes it possible to control the size and shape of a polymer obtained by polymerization of the silica source and to produce almost uniformly sized spherical fine particles. In particular, when an alkoxysilane having an organic group is used as the silica source, the size and shape of the particles tend to be irregular, but the use of the liquid mixture containing alcohol makes it possible to prevent deviations in the shape and the like of the particles caused by the organic group and to obtain uniformly sized and shaped particles.

The prior art document “Microporous and Mesoporous Materials 2006, 93, 190-198” discloses that mesoporous silica particles with different shapes are prepared using various types of alcohols. However, in the method of this document, particles with a high porosity cannot be formed because the mesopores are not large enough. In contrast, in the above-described method of the present embodiment, the growth of the particles is inhibited if alcohol is added to the mixture as described above, but still particles with large first mesopores can be obtained.

The alcohol is not particularly limited, but a polyvalent alcohol with two or more hydroxyl groups is preferred because the growth of the particles can be controlled well. Any suitable polyvalent alcohol can be used, but for example, it is preferable to use ethylene glycol, glycerin, 1,3-butylene glycol, propylene glycol, polyethylene glycol, or the like. The amount of the alcohol to be mixed is not particularly limited, but it is preferably about 1000 to 10000 mass % of the silica source, and more preferably about 2200 to 6700 mass %.

Next, in the surfactant-composited silica particle preparing step, the above-described liquid mixture is mixed and stirred to prepare surfactant-composited silica particles. These mixing and stirring cause the silica source to undergo a hydrolysis reaction by means of the alkali and to be polymerized. In preparing the above-described liquid mixture, the liquid mixture may be prepared by adding the silica source to a liquid mixture containing a surfactant, water, an alkali, and a hydrophobic part-containing additive.

As the alkali used for the reaction, any inorganic or organic alkali suitable for the synthesis reaction of surfactant-composited silica particles can be used. For example, an ammonium or an amine alkali as a nitrogenous alkali, or an alkali metal hydroxide is preferably used, and among these, sodium hydroxide is more preferably used.

Preferably, the mixing ratio of the dispersion solvent (containing water and in some cases alcohol) and the silica source in the liquid mixture is 5 to 100 parts by mass of the dispersion solvent per 1 part by mass of the condensation compound obtained by the hydrolysis reaction of the silica source. If the amount of the dispersion solvent is less than this range, the concentration of the silica source is too high and the reaction rate is increased, which may make it difficult to stably form a regular mesostructure. On the other hand, if the amount of the dispersion solvent is more than this range, the yield of mesoporous silica particles is very low, which may make the production method impractical.

Thus, the surfactant-composited silica particles prepared in the surfactant-composited silica particle preparing step constitute the silica cores of the mesoporous silica particles.

(Organosilica Coating Step)

In the organosilica coating step, an organosilica source is further added to these surfactant-composited silica particles (silica cores) to coat the surfaces of the silica particles described above, that is, the surfaces of the silica cores, with organosilica. In this case, if a surfactant (a second surfactant) is used but a hydrophobic part-containing additive is not used, second mesopores smaller in size than the first mesopores can be easily formed in the organosilica coating portions.

For example, first, a liquid mixture containing surfactant-composited silica particles, water, an alkali, and an organosilica source is prepared. As the surfactant-composited silica particles, the particles obtained in the above-described step may be used without purification. Since micelles are formed in a reaction solution when a surfactant is used, the second mesopores can be easily formed.

When an organosilane [(R²O)₃Si—R¹—Si(R²O)₃] in which silicon alkoxide groups [Si(OR²)₃] are bonded to both sides of an organic group (R¹) is used as the organosilica source, a structure in which two silicon atoms in a silica framework are bridged by an organic group can be easily formed.

Examples of the organic group (R¹) bridging two silicon atoms include a methylene group, an ethylene group, a trimethylene group, a tetramethylene group, a 1,2-butylene group, a 1,3-butylene group, a 1,2-phenylene group, a 1,3-phenylene group, a 1,4-phenylene group, a biphenyl group, a toluyl group, a diethylphenylene group, a vinylene group, a propenylene group, and a butenylene group. A methylene group, an ethylene group, a vinylene group, and a phenylene group are particularly preferred because the organosilica coating portion with high structural regularity can be formed.

As the surfactant for use in the organosilica coating step, the same surfactant as that used in the surfactant-composited silica particle preparing step (the first surfactant) may be used. A different surfactant may be used. The use of the same surfactant makes the production easier.

The mixing ratio of the organosilica source and the surfactant is not particularly limited, but the weight ratio thereof is preferably 1:10 to 10:1. If the amount of the surfactant is outside this range of weight ratios relative to the silica source, the regularity of the structure of the resulting product is more likely to decrease, which may make it difficult to obtain mesoporous silica particles with a regular array of mesopores. In particular, when the weight ratio is 100:75 to 100:100, mesoporous silica particles with a regular array of mesopores can be easily obtained.

Next, in the organosilica coating step, the above-described liquid mixture is mixed and stirred to form the organosilica coating portions on the surfaces of the surfactant-composited silica particles. These mixing and stirring cause the organosilica source to undergo a hydrolysis reaction by means of the alkali and to be polymerized. The organosilica coating portions are formed on the surfaces of the surfactant-composited silica particles. In preparing the above-described liquid mixture, the liquid mixture may be prepared by adding the surfactant-composited silica particles to a liquid mixture containing a surfactant, water, an alkali, and an organosilica source.

As the alkali for use in the reaction, the same alkali as that used in the surfactant-composited silica particle preparing step may be used. A different alkali may be used. The use of the same alkali makes the production easier.

Preferably, the mixing ratio of the organosilica source to be added and the surfactant-composited silica particles in the liquid mixture is 0.1 to 10 parts by mass of the organosilica source per 1 part by mass of the silica source for use in forming the surfactant-composited silica particles. If the amount of the organosilica source is less than this range, a sufficiently thick coating may not be obtained. On the other hand, if the amount of the organosilica source is more than this range, the organosilica coating portion is too thick, which may make it difficult to obtain a sufficient effect of voids.

In the organosilica coating step, it is preferable to use, as the organosilica source, a mixture of a tetraalkoxysilane such as tetraethoxysilane (TEOS) and a surfactant such as hexadecyltrimethylammonium bromide (CTAB). It is desirable to use TEOS as the tetraalkoxysilane. The use of a mixture containing TEOS makes it possible to further enhance the structural regularity of the organosilica coating portion. The amount of TEOS added to the mixture can be 0.1 to 10 parts by mass per 1 part by mass of the organosilica source, and preferably 0.5 to 2 parts by mass. When TEOS is used, CTAB is suitably used. The amount of CTAB added to the mixture can be 0.1 to 10 parts by mass per 1 part by mass of the silica source for use in forming the surfactant-composited silica particles.

It is also preferable to perform the organosilica coating step twice or more or three times or more. As a result, a multilayer organosilica coating portion can be obtained, and thereby the openings of the first mesopores can be covered more reliably.

The stirring temperature in the organosilica coating step is preferably room temperature (for example, 25° C.) to 100° C. The stirring time in the organosilica coating step is preferably 30 minutes to 24 hours. When the stirring temperature and the stirring time are in these ranges, it is possible to form sufficiently thick organosilica coating portions on the surfaces of the surfactant-composited silica particles serving as the silica cores while increasing the production efficiency.

(Removing Step)

After the surfactant-composited silica particles (silica cores) are coated with the organosilica coating portions (organosilica shells) in the organosilica coating step, the surfactant and the hydrophobic part-containing additive contained in the surfactant-composited silica particles are removed in the removing step. After the surfactant and the hydrophobic part-containing additive are removed, mesoporous silica particles having first mesopores and second mesopores can be obtained.

In order to remove the surfactant and the hydrophobic part-containing additive serving as a template from the silica particles composited with the surfactant, the surfactant-composited silica particles can be calcined at a temperature at which the template is decomposed. However, in this removing step, it is preferable to remove the template by extraction in order to prevent the aggregation of particles and to enhance the dispersibility thereof in a medium. For example, the template can be extracted and removed by acid.

It is also preferable to perform a step of silylating the surfaces of the surfactant-composited silica particles while removing the surfactant from the first mesopores and the second mesopores of the surfactant-composited silica particles by mixing acid and alkyldisiloxane. In that case, the surfactant in the mesopores is extracted by the acid and siloxane bonds in the organosilicon compound are activated by the acid through a cleavage reaction. Thus, silanol groups on the surfaces of the silica particles can be alkyl-silylated. This silylation serves to protect the surfaces of the particles with hydrophobic groups and to prevent the first mesopores and the second mesopores from collapsing through hydrolysis of the siloxane bonds. In addition, the silylation serves to inhibit aggregation of particles which may occur due to condensation of silanol groups between the particles.

As the alkyldisiloxane, hexamethyldisiloxane is preferably used. When hexamethyldisiloxane is used, trimethylsilyl groups can be introduced, which means that the surfaces of the particles can be protected with small functional groups.

Any acid can be mixed with the alkyldisiloxane as long as it has the effect of cleaving the siloxane bond. For example, hydrochloric acid, nitric acid, sulfuric acid, hydrogen bromide, or the like can be used. Preferably, the amount of the acid added is adjusted such that the pH of the resulting reaction solution is less than 2 in order to accelerate the extraction of the surfactant and the cleavage of the siloxane bond.

It is preferable to use a suitable solvent when the acid and the organosilicon compound having a siloxane bond in the molecule are mixed. The use of the solvent facilitates the mixing. It is preferable to use an alcohol with amphiphilic properties as the solvent so that the hydrophilic silica nanoparticles and the hydrophobic alkyldisiloxane are mixed well. For example, isopropyl alcohol can be used.

After the surfactant-composited silica particles are synthesized, the reaction by means of the acid and the alkyldisiloxane may be carried out in the reaction solution used for the reaction of forming the organosilica coating portions. In that case, there is no need to separate and collect the particles from the solution after the surfactant-composited silica particles are synthesized or the organosilica coating portions are formed, and the separating and collecting step can be omitted. Therefore, the production process can be simplified. In addition, since the separating and collecting step is omitted, the surfactant-composited silica particles can be uniformly reacted without being aggregated. Therefore, the resulting mesoporous silica particles remain in the form of discrete fine particles.

The removing step can be performed, for example, as follows. The acid and the alkyldisiloxane are mixed into the reaction solution used for forming the organosilica coating portions, and the resulting mixture is stirred for about 1 minute to 50 hours, preferably for about 1 minute to 8 hours, under heating conditions of about 40° C. to 150° C., preferably about 40° C. to 100° C. Thereby, the surfactant is extracted from the mesopores by the acid, and at the same time, the alkyldisiloxane is activated through a cleavage reaction caused by the acid. As a result, the first mesopores and the second mesopores as well as the surfaces of the particles can be alkyl-silylated.

Herein, it is also preferable that the surfaces of the surfactant-composited silica particles have functional groups that are not silylated by the mixture of the acid and the alkyldisiloxane. As a result, some of the functional groups remain unsilylated on the surfaces of the mesoporous silica particles. Therefore, the surfaces of the mesoporous silica particles can be easily treated with a substance that reacts with these unsilylated functional groups, or chemical bonds can be easily formed with that substance on the surfaces of the mesoporous silica particles. Therefore, it is easy to perform a surface treatment reaction such as a formation of chemical bonds by a reaction between the mesoporous silica particles and the functional groups in the resin forming the matrix. These functional groups can be introduced using the silica source containing them in the preceding steps.

The functional groups that are not silylated by the mixture of the acid and the organosilicon compound having a siloxane bond in the molecule are not particularly limited, but an amino group, an epoxy group, a vinyl group, a mercapto group, a sulfide group, an ureido group, a methacryloxy group, an acryloxy group, a styryl group, or the like is preferred.

The mesoporous silica particles prepared in the removing step can be used in a liquid dispersion, a composition, or a molded article after they are collected by centrifugation, filtration, or the like, and then dispersed in a medium or subjected to media exchange by dialysis or the like.

According to the method for producing mesoporous silica particles as described above, it is possible to form the first mesopores by the surfactant and incorporate the hydrophobic part-containing additive into the surfactant micelles so as to increase the micelle size in the course of the alkoxysilane hydrolysis reaction under the alkaline conditions, and thereby to form mesoporous silica particles in the form of fine particles with increased porosity. In addition, it is possible to obtain mesoporous silica particles having organosilica coating capable of inhibiting penetration of the matrix material into the mesopores of the particles.

[Composition]

A mesopoous silica particle-containing composition can be obtained by adding the above-described mesoporous silica particles to a matrix material. A molded article having properties such as a low refractive index (Low-n), a low dielectric constant (Low-k), and/or a low thermal conductivity can be easily produced from this mesoporous silica particle-containing composition. Since the mesoporous silica particles are uniformly dispersed in the matrix material in the composition, it is possible to produce a homogeneous molded article using this composition.

The matrix material is not particularly limited as long as it does not impair the dispersibility of the mesoporous silica particles. Examples the matrix material include polyester resins, acrylic resins, urethane resins, vinyl chloride resins, epoxy resins, melamine resins, fluorine resins, silicone resins, butyral resins, phenol resins, vinyl acetate resins, and fluorene resins. These resins may be ultraviolet curable resins, thermosetting resins, electron beam curable resins, emulsion resins, water-soluble resins, hydrophilic resins, mixtures of these resins, copolymers and modified forms of these resins, hydrolyzable organosilicon compounds such as alkoxysilanes. An additive may be added to the composition as necessary. Examples of the additive include luminescent materials, electrically conductive materials, color forming materials, fluorescent materials, viscosity adjusting materials, resin curing agents, and resin curing accelerators.

[Molded Article]

A mesoporous silica particle-containing molded article can be obtained by molding the above-described mesoporous silica particle-containing composition. It is thus possible to obtain a molded article having properties such as a low refractive index (Low-n), a low dielectric constant (Low-k), and/or a low thermal conductivity. Since the mesoporous silica particles have good dispersibility, the mesoporous silica particles are uniformly arranged in the matrix in the molded article, and thus a molded article with less variation in performance can be obtained. In addition, since the mesoporous silica particles are coated with organosilica, penetration of the matrix material into the mesopores of the mesoporous silica particles is inhibited in the resulting molded article.

The method for producing a molded article containing the mesoporous silica particles is not limited as long as the mesoporous silica particle-containing composition can be formed into a desired shape. Printing, coating, extrusion molding, vacuum molding, injection molding, laminate molding, transfer molding, foam molding, or the like can be used.

In the case of coating the surface of a substrate, the method for coating the substrate is not particularly limited. The method can be selected from various commonly used coating methods such as brush coating, spray coating, dipping (dip coating), roll coating, flow coating, curtain coating, knife coating, spin coating, table coating, sheet coating, sheet-type coating, die coating, bar coating, and doctor blade coating. A method such as cutting or etching also can be used to form a solid into a desired shape.

In the molded article, the mesoporous silica particles are preferably composited with the matrix material by chemical bonds between them. This allows the mesoporous silica particles and the matrix material to be bonded more firmly. The term “composite” or “composited” refers to being combined with another component to form a complex by a chemical bond therebetween.

The structure of the chemical bonds formed between the mesoporous silica particles and the matrix material is not particularly limited as long as they have functional groups serving to chemically bond them on their surfaces. For example, if one of them has an amino group, the other preferably has an isocyanate group, an epoxy group, a vinyl group, a carbonyl group, a Si—H group, or the like, and in this case, a chemical reaction easily occurs between them to form chemical bonds.

Preferably, the molded article exhibits one, or two or more of the properties selected from high transparency, low dielectricity, low refractivity, and low thermal conductivity. A high-quality device can be produced when the molded article exhibits high transparency, low dielectricity, low refractivity, and/or low thermal conductivity. If the molded article exhibits two or more of these properties, a multifunctional molded article can be obtained, and therefore a device that requires multifunctionality can be produced. That is, the mesoporous silica particle-containing molded article has excellent uniformity as well as the properties of a high transparency, a low refractive index (Low-n), a low dielectric constant (Low-k), and/or a low thermal conductivity.

In particular as molded articles utilizing the low refractive index (Low-n) property, organic EL devices and antireflective films, for example, can be mentioned.

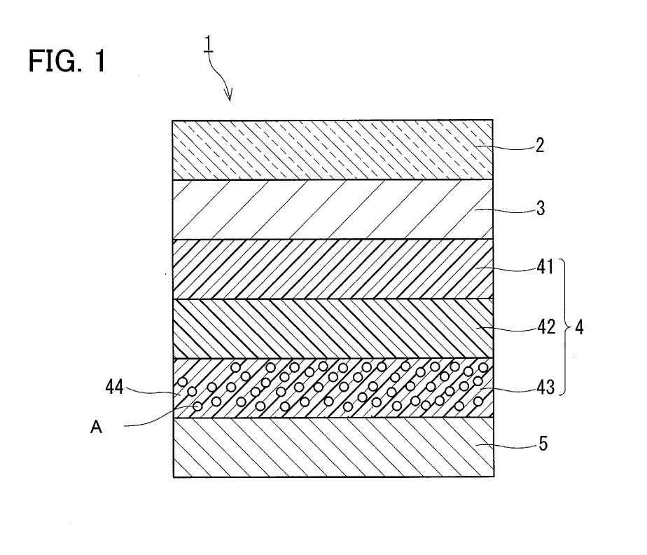

FIG. 1 is an example of an embodiment of an organic EL device.

An organic EL device 1 shown in FIG. 1 is formed by stacking a first electrode 3, an organic layer 4, and a second electrode 5 on the surface of a substrate 2 in this order from the first electrode 3 side. One surface of the substrate 2 opposite to the first electrode 3 side surface is exposed to the outside (for example, the atmosphere). The first electrode 3 has a light transmitting property and serves as an anode of the organic EL device 1. The organic layer 4 is formed by stacking a hole injection layer 41, a hole transport layer 42, and a light emitting layer 43 in this order from the first electrode 3 side. Mesoporous silica particles A are dispersed in a light emitting material 44 in the light emitting layer 43. The second electrode 5 has a light reflecting property and serves as a cathode of the organic EL device 1. A hole blocking layer, an electron transport layer, and an electron injection layer may further be stacked between the light emitting layer 43 and the second electrode 5 (not shown). In the organic EL device 1 thus configured, when a voltage is applied between the first electrode 3 and the second electrode 5, the first electrode 3 injects holes into the light emitting layer 43 and the second electrode 5 injects electrons into the light emitting layer 43. The holes and the electrons are recombined with each other in the light emitting layer 43 and thereby excitons are generated. When the excitons return to the ground state, light is emitted. The light emitted in the light emitting layer 43 is taken out to the outside through the first electrode 3 and the substrate 2.

Since the light emitting layer 43 contains the above-described mesoporous silica particles A, it has a low refractive index and thus enhances the light emitting efficiency. The light emitting layer 43 also emits light with high intensity. The light emitting layer 43 may have a multilayer structure. For example, the multilayer structure can be obtained by forming the outer layer (or the first layer) of the light emitting layer 43 using a light emitting material not containing the mesoporous silica particles A and forming the inner layer (or the second layer) of the light emitting layer 43 using a light emitting material containing the mesoporous silica particles A. In this case, the area of contact between the light emitting materials and the other layers increases at the interfaces therebetween. Thus, higher light emitting efficiency is achieved.

### EXAMPLES

Next, the present invention is described specifically with reference to Examples.

[Production of Mesoporous Silica Particles]

### Example 1

### Synthesis of Surfactant-Composited Silica Particles

133 g of H₂O, 2.0 g of 1N—NaOH aqueous solution, 20 g of ethylene glycol, 1.20 g of hexadecyltrimethylammonium bromide (CTAB), 1.54 g of 1,3,5-trimethyl benzene (TMB) (ratio of amount of substance: TMB/CTAB=4), 1.29 g of tetraethoxysilane (TEOS), and 0.23 g of γ-aminopropyltriethoxysilane (APTES) were mixed in a separable flask equipped with a cooling tube, a stirrer, and a thermometer, and the resulting mixture was stirred at 60° C. for 4 hours. Thus, surfactant-composited silica particles were prepared.

Formation of Organosilica Coating Portion:

0.75 g of TEOS and 0.64 g of 1,2-bis(triethoxysilyl)ethane were added to a reaction solution of the surfactant-composited silica particles, and the resulting mixture was stirred for 2 hours.

Extraction of Template and Preparation of Solvent Dispersion:

30 g of isopropyl alcohol (IPA), 60 g of 5N—HCl, and 26 g of hexamethyldisiloxane were mixed, and the resulting mixture was stirred at 72° C. Then, a synthesis reaction solution containing the previously prepared surfactant-composited silica particles was added to the mixture, and stirred and refluxed for 30 minutes. By the procedure described above, the surfactant and a hydrophobic part-containing additive as a template were extracted from the surfactant-composited silica particles. Thus, a dispersion of mesoporous silica particles was obtained.

The dispersion of mesoporous silica particles was centrifuged at a centrifugal force of 12,280 G for 20 minutes, and then the separated liquid was removed. IPA was added to the precipitated solid phase, and the particles were shaken in IPA with a shaker to wash the mesoporous silica particles. The resulting liquid was centrifuged at a centrifugal force of 12,280 G for 20 minutes, and the separated liquid was removed. Thus, mesoporous silica particles were obtained.

3.8 g of IPA was added to 0.2 g of the mesoporous silica particles thus prepared and the mesoporous silica particles were re-dispersed with a shaker. As a result, mesoporous silica particles dispersed in isopropanol were obtained. Mesoporous silica particles dispersed in acetone and in xylene, respectively, were obtained by the same procedure.

### Example 2

Surfactant-composited silica particles were synthesized in the same procedure as in Example 1. 0.75 g of TEOS and 0.50 g of 1,4-bis(triethoxysilyl)benzene (BTEB) were added to this reaction solution, and stirred for 2 hours. Thus, organosilica coating portions were formed. Under the same conditions as in Example 1, the template was extracted, and IPA, acetone, and xylene dispersions were prepared.

### Example 3

Surfactant-composited silica particles were synthesized in the same procedure as in Example 2. 1.2 g of CTAB was added to this reaction solution, and stirred at 60° C. for 10 minutes. Then, 0.75 g of TEOS and 0.50 g of BTEB were added to the resulting mixture, and stirred for 2 hours. Thus, organosilica coating portions were formed. Under the same conditions as in Example 1, the template was extracted, and IPA, acetone, and xylene dispersions were prepared.

### Comparative Example 1

Surfactant-composited silica particles were synthesized under the same conditions as in Example 1, except that organosilica coating portions were not formed. Then, under the same conditions as in Example 1, the template was extracted and the particles were washed to obtain mesoporous silica particles. Under the same conditions as in Example 1, these mesoporous silica particles were dispersed in IPA, acetone, and xylene, respectively.

### Comparative Example 2

Surfactant-composited silica particles were synthesized in the same procedure as in Example 1. 1.29 g of TEOS and 0.25 g of phenyltriethoxysilane were added to this reaction solution, and stirred for 2 hours. Thus, organosilica coating portions were formed. Under the same conditions as in Example 1, the template was extracted, and IPA, acetone, and xylene dispersions were prepared. As a result, mesoporous silica particles, in which the organosilica forming the organosilica coating portions did not include a bridged-type organosilica having a structure in which two silicon atoms in a silica framework are bridged by an organic group, were obtained.

[Structural Comparison of Mesoporous Silica Particles]

The mesoporous silica particles of Examples 1 and 2 and Comparative Example 1 were subjected to heat treatment at 150° C. for 2 hours to obtain dry powder samples. Then, the powder samples were analyzed by nitrogen adsorption measurement and transmission electron microscopy (TEM) observation.

(Nitrogen Adsorption-Desorption Measurement)

The nitrogen adsorption-desorption isotherms were measured on an Autosorb-3 (Quantachrome Instrument). The BET specific surface area and pore volumes of the mesoporous silica particles were calculated from the adsorption branch. The pore-size distribution was evaluated using the BJH model.

Table 1 shows the BET specific surface area, pore volume and the peak values of BJH pore size distribution.

The BET specific surface areas and pore volumes of the particles of Examples 1 to 3 are comparable to those of the particles of Comparative Example 1, which shows that these particles have high porosity. The particles of Example 1 had two different size mesopores, first mesopores with a pore diameter of 4.7 nm and second mesopores with a pore diameter of 2.9 nm. The particles of Example 2 also had two different size mesopores, first mesopores with a pore diameter of 4.2 nm and second mesopores with a pore diameter of 2.7 nm. The particles of Example 3 also had two different size mesopores, first mesopores with a pore diameter of 4.2 nm and second mesopores with a pore diameter of 2.7 nm. It was thus confirmed that in the particles of Examples 1 to 3, the second mesopores smaller in size than the first mesopores were formed. On the other hand, it was confirmed that in the particles of Comparative Example 1, only the first mesopores with a pore diameter of 4.4 nm were formed.

TABLE 1

| | BET specific | | |
|---|---|---|---|
| | surface area | Pore volume | BJH pore diameter |
| | [m²g⁻¹] | [cm³g⁻¹] | [nm] |
| Example 1 | 824 | 2.1 | 2.9 and 4.7 |
| Example 2 | 984 | 2.0 | 2.7 and 4.2 |
| Example 3 | 950 | 1.9 | 2.7 and 4.2 |
| Com. Example 1 | 811 | 1.8 | 4.4 |

(TEM Observation)

The microstructure of the mesoporous silica particles of Examples 1 to 3 and Comparative Example 1 were observed by TEM with JEM2100F (JEOL).

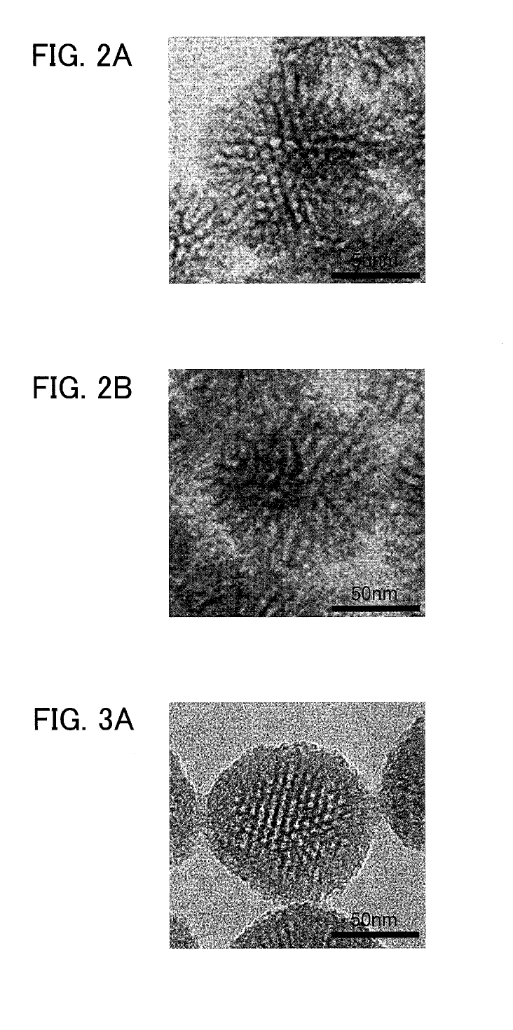

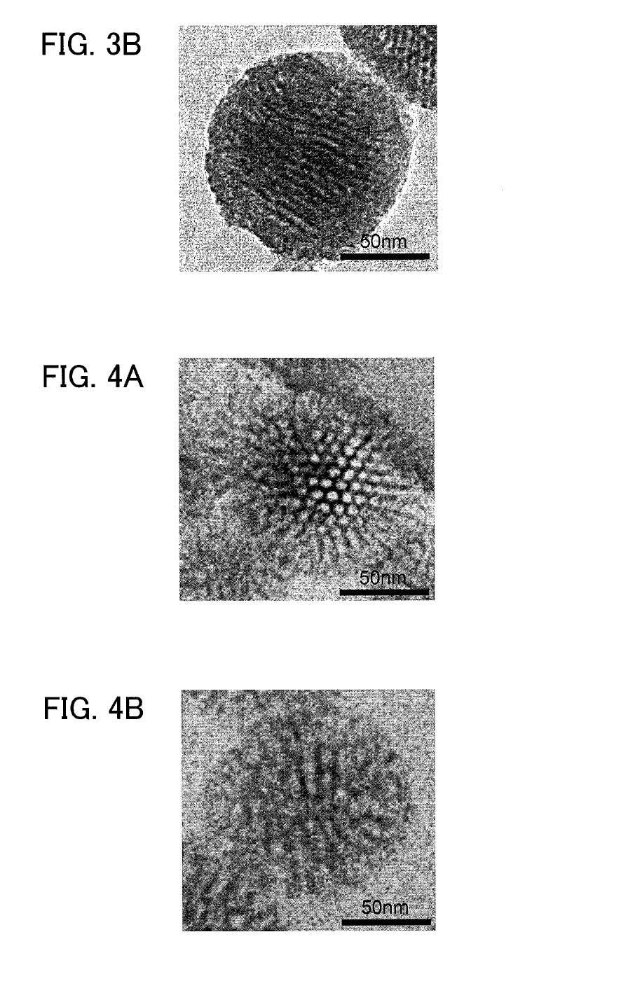

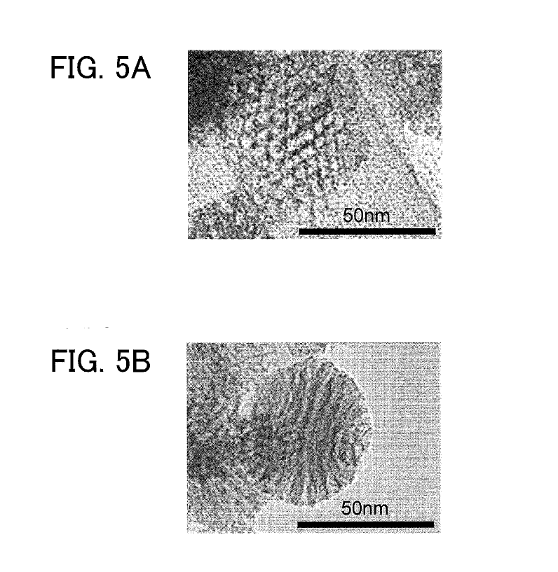

FIG. 2A and FIG. 2B show the TEM images of the mesoporous silica particles of Example 1. FIG. 3A and FIG. 3B show the TEM images of the mesoporous silica particles of Example 2. FIG. 4A and FIG. 4B show the TEM images of the mesoporous silica particles of Example 3. FIG. 5A and FIG. 5B show the TEM images of Comparative Example 1.

The particle diameter of the particles obtained in Examples 1 to 3 were about 70 nm. On the other hand, the particle diameter of the particles obtained in Comparative Example 1 was about 50 nm. It was thus confirmed that the silica coating portion with a thickness of about 10 nm was formed by the regrowth of the particle to increase the particle diameter in Examples. An ordered array of mesopores of 4 to 5 nm was identified in the inner portion of each particle in Examples 1 to 3. These mesopores are considered as the first mesopores determined by the nitrogen adsorption-desorption measurement. Therefore, the second mesopores of 2.9 nm in Example 1, those of 2.7 nm in Examples 2 and 3, which were determined by the nitrogen adsorption-desorption measurement, are thought to be formed in the silica coating portions. On the other hand, in Comparative Example 1, an ordered array of mesopores of 4 to 5 nm was identified throughout the particle.

[Comparison of Dispersibility of Mesoporous Silica Particles in Solvent]

(Dynamic Light Scattering Measurement)

The particle size distribution in each solvent was measured using ELSZ-2 (Otsuka Electronics). Table 2 shows the results.

It was confirmed that the dispersibility of the particles obtained in Examples 1 and 2 in the solvents was improved compared to that of the particles having no organosilica coating portion obtained in Comparative Example. In particular, the dispersibility in hydrophobic xylene was significantly improved. Probably, this is the effect of organic groups contained in the organosilica coating portions. It was also confirmed that the dispersibility of the particles obtained in Examples 1 and 2 in the solvents was improved compared to that of the particles obtained in Comparative Example 2. Probably, this is the effect of more uniform arrangement of organic groups in the organosilica coating portions.

TABLE 2

| | Particle size distribution [nm] | | |
|---|---|---|---|
| | IPA | Acetone | Xylene |
| Example 1 | 101.8 ± 30.4 | 105.5 ± 51.3 | 312.1 ± 153.9 |
| Example 2 | 102.9 ± 40.6 | 103.7 ± 45.0 | 206.2 ± 103.6 |
| Com. Example 1 | 90.4 ± 28.4 | 150.2 ± 72.2 | 2913.7 ± 894.0 |
| Com. Example 2 | 103.6 ± 42.0 | 108.3 ± 50.5 | 315.0 ± 155.8 |

### Organic EL Device

### Example A1

The organic EL device having a multilayer structure shown in FIG. 1 was prepared.

As the substrate 2, an alkali-free glass plate with a thickness of 0.7 mm (No. 1737, Corning) was used. Sputtering was performed using an ITO target (Tosoh) to form an ITO layer with a thickness of 150 nm on the surface of the substrate 2. The glass substrate on which the ITO layer was formed was subjected to annealing treatment at 200° C. for one hour in an Ar atmosphere. Thus, the first electrode 3 of the ITO layer was formed as a light-transmissive anode with a sheet resistance of 18 Ω/square. The refractive index of the first electrode 3 at a wavelength of 550 nm was 2.1 when measured with SCI FilmTek.

Next, polyethylenedioxythiophene/polystyrenesulfonate (PEDOT-PSS) (“Baytron P AI4083”, Starck-V Tech, PEDOT:PSS=1:6) was applied onto the surface of the first electrode 3 by a spin coater to form a layer with a thickness of 30 nm, and baked at 150° C. for 10 minutes. Thus, the hole injection layer 41 was formed. The refractive index of the hole injection layer 41 at a wavelength of 550 nm was 1.55 when measured in the same manner as for the first electrode 3.

Next, a solution obtained by dissolving TFB (poly[9,9-dioctylfluorenyl-2,7-diyl)-co-(4,4′-(N-(4-sec-butylphenyl))diphenylamine)]) (Hole Transport Polymer ADS259BE, American Dye Source) in a THF solvent was applied onto the surface of the hole injection layer 41 by a spin coater to form a layer with a thickness of 12 nm. This TFB coating was baked at 200° C. for 10 minutes to form the hole transport layer 42. The refractive index of the hole transport layer 42 at a wavelength of 550 nm was 1.64.

Next, a solution obtained by dissolving a red-emitting polymer (Light Emitting Polymer ADS111RE, American Dye Source) in a THF solvent was applied onto the surface of the hole transport layer 42 by a spin coater to form a layer with a thickness of 20 nm, and baked at 100° C. for 10 minutes. Thus, a red-emitting polymer layer serving as the outer layer of the light-emitting layer 43 was formed.

A solution obtained by dispersing the mesoporous silica particles prepared in Example 1 in 1-butanol was applied onto the surface of the red-emitting polymer layer to form a layer, and the red-emitting polymer ADS111RE was further applied thereon by a spin coater to form a layer so that a layer including the layer formed by applying the mesoporous silica particles and the layer formed by applying the red-emitting polymer had a thickness of 100 nm in total. The resulting layer was baked at 100° C. for 10 minutes to obtain the light-emitting layer 43. The total thickness of the light-emitting layer 43 was 120 nm. The refractive index of the light-emitting layer 43 at a wavelength of 550 nm was 1.53.

Finally, 5 nm thick Ba and 80 nm thick aluminum were deposited on the surface of the light-emitting layer 43 by vacuum deposition. Thus, the second electrode 5 was prepared.

The organic EL device 1 of Example A1 was thus obtained.

### Comparative Example A1

An organic EL device of Comparative Example A1 was obtained in the same procedure as in Example A1, except that the mesoporous silica particles of Comparative Example 1, on which the organosilica coating portion was not formed, were used as the particles mixed into the light-emitting layer 43. In this device, the refractive index of the light-emitting layer 43 at a wavelength of 550 nm was 1.55.

### Comparative Example A2

An organic EL device was obtained in the same procedure as in Example A1, except that mesoporous silica particles were not mixed into the light-emitting layer. In this device, the refractive index of the light-emitting layer 43 at a wavelength of 550 nm was 1.67.

(Evaluation Test)

For the organic EL devices 1 of Example A1 and Comparative Examples A1 and A2 prepared as described above, the evaluation test was performed. In this evaluation test, an electric current having a current density of 10 mA/cm² was applied between the electrodes 3 and 5 (see FIG. 1), and light emitted to the atmosphere was measured using an integrating sphere. A hemispherical lens made of glass was placed on the emitting surface of the organic EL device 1 via a matching oil having the same refractive index as the glass, and light reaching the substrate 2 from the light-emitting layer 43 was measured in the same procedure as described above. Based on these measurement results, the external quantum efficiency of the light emitted to the atmosphere and that of the light reaching the substrate were calculated. The external quantum efficiency of the light emitted to the atmosphere was calculated from the electric current supplied to the organic EL device 1 and the amount of the light emitted to the atmosphere. The external quantum efficiency of the light reaching the substrate was calculated from the electric current supplied to the organic EL device 1 and the amount of the light reaching the substrate.

Table 3 shows the results of the evaluation test. The external quantum efficiencies of the light emitted to the atmosphere and the light reaching the substrate of each organic EL device 1 were calculated relative to the efficiencies of Comparative Example A2.

TABLE 3

| | | External quantum efficiency | |
|---|---|---|---|
| | | Light | |
| | Refractive index of | emitted to | Light reaching |
| | light-emitting layer | atmosphere | substrate |
| Example A1 | 1.53 | 1.12 | 1.38 |
| Com. Example A1 | 1.55 | 1.07 | 1.23 |
| Com. Example A2 | 1.67 | 1.01 | 1.00 |

The organic EL devices 1 of Example A1 and Comparative Example A1 containing mesoporous silica particles were compared with the organic EL device 1 of Comparative Example A2 containing no mesoporous silica particle. As shown in Table 3, the device of Example A1 and Comparative Example A1 exhibited higher external quantum efficiencies than the device of Comparative Example A2. The organic EL device 1 of Example A1 was compared with the organic EL device 1 of Comparative Example A1 in which mesoporous silica particles had no outer peripheral portion covering the inner portion, that is, mesoporous silica particles were not covered by the organosilica coating portions. The light-emitting layer 43 of the device of Example A1 exhibited a lower refractive index than that of the device of Comparative Example A1, and thus the former device exhibited a higher external quantum efficiency than the latter device.

### INDUSTRIAL APPLICABILITY

The mesoporous silica particles of the present invention serving as high porosity fine particles can be applied to low reflectance (Low-n) materials, low dielectric constant (Low-k) materials, and further low thermal conductivity materials. The mesoporous silica particles of the present invention can be suitably used in organic EL devices, antireflective films, etc., for example, when they are applied to low refractive index (Low-n) materials.

1. Mesoporous silica particles each comprising:
an inner portion having first mesopores; and
an outer peripheral portion covering the inner portion,
wherein
the outer peripheral portion comprises an organosilica coating portion made of organosilica, and
the organosilica comprises a bridged-type organosilica in which two silicon atoms in a silica framework are bridged by an organic group.

2. The mesoporous silica particles according to claim 1, wherein the organosilica coating portion has second mesopores smaller in size than the first mesopores.

3. A method for producing mesoporous silica particles, comprising:
a surfactant-composited silica particle preparing step of preparing surfactant-composited silica particles by mixing a first surfactant, water, an alkali, a hydrophobic part-containing additive, and a silica source, the hydrophobic part-containing additive including a hydrophobic part serving to increase a volume of a micelle formed by the first surfactant; and
an organosilica coating step of coating at least part of a surface of each of the surfactant-composited silica particles with organosilica by adding an organosilica source to the surfactant-composited silica particles.

4. The method for producing mesoporous silica particles according to claim 3, wherein in the organosilica coating step, the organosilica source and a second surfactant are added to the surfactant-composited silica particles so as to coat the at least part of the surface of each of the surfactant-composited silica particles with organosilica composited with the second surfactant.

5. A mesoporous silica particle-containing composition, comprising:
the mesoporous silica particles according to claim 1; and
a matrix material.

6. A mesoporous silica particle-containing molded article, obtained by molding the mesoporous silica particle-containing composition according to claim 5 into a predetermined shape.

7. An organic electroluminescence device comprising:
a first electrode;
a second electrode; and
an organic layer disposed between the first electrode and the second electrode and comprising a light-emitting layer,
wherein
the organic layer comprises the mesoporous silica particles according to claim 1.
